(19) United States
(12) Patent Application Publication
(10) Pub. No.: US 2005/0243947 A1
(43) Pub. Date: Nov. 3, 2005

(54) Method and apparatus for processing a digital data stream

(75) Inventors: John A. Harold-Barry, Southampton (GB); Trevor G.R. Hall, Twickenham (GB)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., BA Eindhoven (NL)

(21) Appl. No.: 10/515,943

(22) PCT Filed: May 21, 2003
(86) PCT No.: PCT/IB03/02276

§ 371 Date: Nov. 23, 2004

(30) Foreign Application Priority Data
May 25, 2002 (GB) 0212080.6

(51) Int. Cl. H03C 1/52

(52) U.S. Cl. 375/300

(57) ABSTRACT

The invention provides for a method and apparatus for of processing digital data (10), comprising the steps of forming a plurality of discrete bursts of data (12) from the digital data, charging a charge storage device (32) during periods (14) between the discrete bursts of data, and subsequently discharging the charge storage device (32) during the discrete bursts of data (12) so as to provide at least part of the power required during the data bursts (12) and so as to reduce peak power requirements while allowing for the transfer of data at rates less than a minimum data rate set for data recordal/playback

The present invention relates to a method and apparatus for processing a digital data stream and, in particular, to a method and apparatus for processing a digital data stream as part of a digital signal recording/playback arrangement.

Due to an ongoing desire to reduce the physical size of digital signal processing devices, such as those offering, or requiring, the recording, or playback, of digital data, the size and capacity of the local power supply is an ever relevant issue particularly for portable devices.

With such devices, it can prove particularly advantageous to reduce the power requirements so as to increase the period of usage prior to battery replacement/recharging, and also since a less powerful, and possibly smaller, power supply device need only then be mounted within the portable device.

For example, IBM micro drives generally conform to the so-called compact flash+standard. The principal difference between the original compact flash standard and the compact flash+standard is that the maximum peak power to be drawn is increased from 100 mA @ 3V to 500 mA @ 3V. As should be appreciated, the standard to which a particular device conforms has a direct effect on the nature of products within which it is used on the size of the market that might be available to such devices. Thus, if power savings can be achieved, this can also have the added benefit of extending the potential market for a particular device. In particular, many Portable Digital Assistances (PDAs), cameras and other hand-portable devices can only supply the lower power levels noted above. Such limitations are also relevant to small optical devices, some of which have been proposed for use within mobile telephone handsets.

Issue relating to the power requirements for, for example, optical disk recording/playback systems are known from U.S. Pat. No. 5,182,741 in which the power requirement varies according to recording frequency; and U.S. Pat. No. 5,550,799 in which the power is varied depending upon the nature of the signal being processed.

However, such arrangements are necessarily limited and tied to the operating characteristics upon which the potential power saving is based.

The present invention seeks to provide for a method and apparatus for processing a digital data stream and which offers advantages in reducing the power requirements for such processing.

According to a first aspect of the present invention, there is provided a method of processing digital data, comprising the steps of forming a plurality of discrete bursts of data from the digital data, charging a charge storage device during periods between the discrete bursts of data, and subsequently discharging the charge storage device during the discrete bursts of data so as to provide at least part of the power required during the data bursts.

The present invention also provides for a related digital data processing device including means for forming a plurality of discrete bursts of data from digital data, charge storage means arranged to be charged via a power supply for the device, and control means arranged to charge the charge storage means during periods between the discrete bursts of data, and subsequently to discharge the charge storage device during the discrete bursts of data so as to provide for at least part of the power required by the device during the data bursts.

The subject matter of the present invention is particularly advantageous in reducing peak power requirements for a data processing system by advantageously dividing power-on time within the system so as to be effectively smoothed by, for example, a capacitor.

Data processing systems as record/playback systems often require large peaks of power, which might be beyond the efficient specification of a power supply/battery for a mobile device. The appropriately controlled division of, for example, the data stream into time separated chunks in the present invention can serve to overcome such a problem by controlling the width of the aforesaid chunks so that energy required during the processing of the chunks can be supplied by discharge from a capacitor. Advantageously, the time gap between the chunks can advantageously be readily controlled so that peak power into the capacitor is lower than the systems peak power capability.

The subject matter of Claim 2 is particularly useful in further extending the advantageous peak-power reduction afforded by the present invention.

The subject matter of Claims 4-7 provides particularly advantageous, simple, and potentially space-efficient, means for providing the temporary storage, and subsequent discharging of what effectively functions as a supplementary power source.

The subject matter of Claims 8-10 relate the subject matter of the present invention to, for example, optical drives used in portable devices.

It will therefore be appreciated, that the present invention can advantageously be employed in relation to the recording/playback arrangement for optical disk devices and particularly those which require a minimum bit rate at which recording or playback can take place. Such minimum bit rate is generally in the order of 33 Mbits/s for digital video recording. In this manner, recording or playback of a data stream having a bit rate well below such minimum can then advantageously be achieved in short, repetitive bursts wherein each burst is provided at or above, the aforementioned minimum bit rate. Although with such devices, the peak power consumption would remain high since it is associated with the minimum bit rate for recording/playback, the present invention offers the advantage that, through use of an appropriate charge storage device, the peak-power requirement of the device can actually be reduced by storing power during inactive periods between the aforementioned repetitive bursts, and supplementing the device power supply during active periods defined by the repetitive bursts. Through appropriate choice of the length of the active and inactive periods, sufficient supplementary power can be supplied by discharging the charge storage device so as to noticeably reduce the peak-power consumption of the device.

Yet further, the invention can be arranged such that each data burst may itself consist of multiple active and idle periods wherein the average data rate during a single burst is less than that associated with the minimum bit rate for recording/playback.

The invention is described further hereinafter, by way of example only, with reference to the accompanying drawings in which:

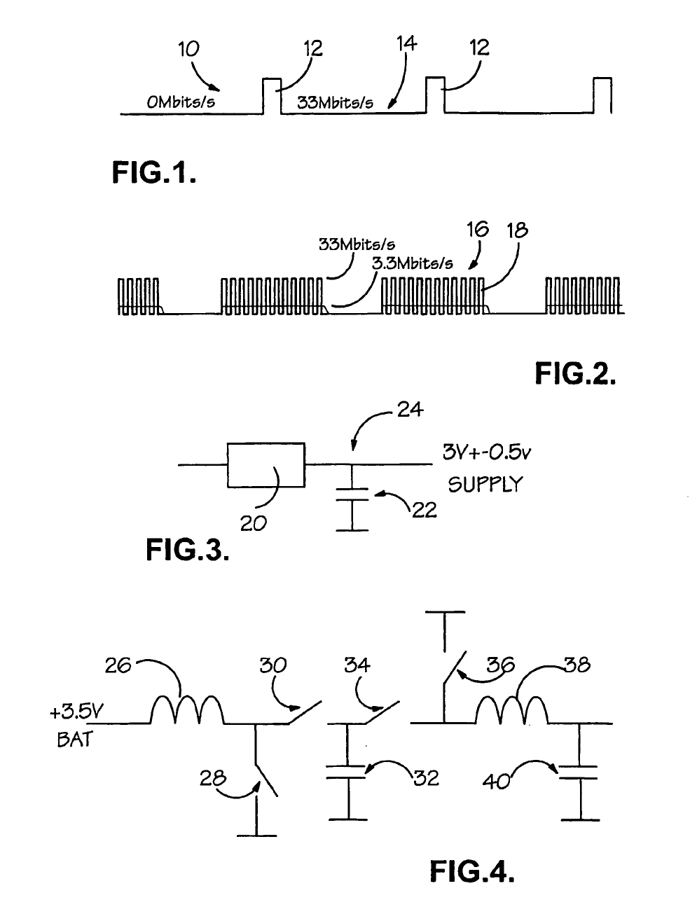

FIG. 1 is a schematic graphical representation of the division of a digital data stream into chunks of data in order to reduce the data rate to below a minimum rate for data recording or playback;

FIG. 2 is a schematic representation of the division of a data stream according to an embodiment of the present invention;

FIG. 3 illustrates a simplified model for achieving the supplementary power supply according to the present invention;

FIG. 4 illustrates a switch-mode power supply for use in accordance with an embodiment of the present invention; and

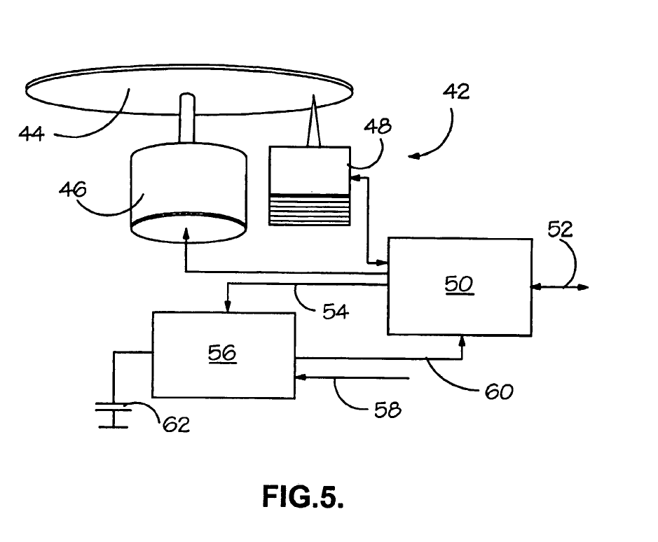

FIG. 5 is a schematic block diagram of an optical device arranged for employing an embodiment of the present invention.

FIG. 1 illustrates a current proposal in which a digital data stream 10, which might have exhibited a bit rate below the minimum required for recording the playback in relation to an optical disk recorder is split into discrete 16 Mbit chunks of data 12 each having a bit rate of 33 Mbits/s. A minimum bit rate of 33 Mbits is chosen as a threshold value in view of its relevant to the ability to record with digital video recording materials.

As will be appreciated from FIG. 1, the digital data stream 10 when divided into the discrete 16 Mbit chunks 12 exhibits inactive periods 14 between those chunks 12.

An example is now discussed in which the data processed comprises digital data recorded on, and played back from an optical disk. Since the digital video recording rate is generally 1.5, a data rate of 33 Mbits/s into a recording drive results in a data stream in the order of 20 Mbits/s output from the drive. Thus, in order to meet a maximum user rate of 1 Mbits/s, the device only effectively has to be on for 1/20^{th} of the time required to meet such a data rate and the average power can be reduced by means of a locally stored energy source without the need for a recording rate in the order of 1.5 Mbits/s. With regard to the peak-power requirements however, the local energy still has to be employed to supplement the power supply still has to be sourced and a battery has been proposed to supply such a source of energy but this is considered possibly prohibitively due to its cost and size.

Through control of the time for which the data burst is required, it is found that at least some of the power required for the data processing can be drawn from the capacitor.

FIG. 2 illustrates an embodiment in which discrete 33 Mbit/s data bursts 16 are themselves each divided into a discrete series of data bursts 18 each of which is short enough in duration to allow for energy required each burst to be sourced from a capacitor.

Given that the cluster size out of the digital video recording error corrector is 64 kbytes, then at 20 Mbits this will take 64e3÷(20e6÷8)=25 ms. With an optimistic power consumption in the region of 750 mW and if a 1 Volt drop is assumed on the capacitor, and it is assumed that the power is supplied from 3 Volts, then:
I=P+V=250 mA, C=IT÷V=0.25 A×0.025 s÷1V=6.25 mF.

If, for example, the data is recovered in 2k chunks, the data would then be read for 2×103÷(20×10⁶÷8)=0.8 ms.

The capacitor need would be in the order of C=IT÷V=0.25 A×0.0008 s÷1V=200 uF.

As will be appreciated, the charge storage device is then thirty-two times smaller, due to the chunk size being thirty-two times smaller. Yet further, if the 2 kbyte chunks were spaced at a ratio of 1:19 mark to space, the peak power would be the same as the mean 750 mW/20=37.5 mW.

However it is appreciated that it will now take at least 20×0.8 ms×32=0.5 s to read an error corrector block but peak consumption can nevertheless then be traded against access time by reducing the mark to space ratio. For example, a ratio of 1:4 would have a peak consumption of 750 mW÷5=150 mW and a delay of 5×0.8 ms×32=125 ms. When streaming at 1 Mbit/s, the power consumption would then be 150 mW for a quarter of the time, and zero for the other three-quarters.

For an optical disk, it should be appreciated that the actual ratio achieved is dependant on the chunk size as a ratio of one disk rotation.

As will be appreciated, a simple capacitor model was chosen above where the average Voltage was 3V and the drop allowed was 1V. This could perhaps be achieved by a simple resistor 20 and capacitor 22 circuit 24 such as that illustrated in FIG. 3.

In the circuit, it will be appreciated that the resistor 20 dissipates power, the energy stored in a capacitor 22 is proportional to the square of the voltage, and a ripple of 1V also results in yet more power dissipation such that a switching regulator is needed.

FIG. 4 illustrates switch-mode power supply suitable for charge storage according to the present invention. The circuit can be operated as follows and comprises a charging inductor 26, a switch 28 to earth, a switch 30 for connection to a capacitor 32, a further switch for discharging the capacitor 32 to a discharge inductor 38, and a further capacitor connected to the inductor 38. A switch 36 is also provided to source current to the discharge inductor 38 when switch 34 is open. The switch 28 is closed until the maximum allowable current is drawn from the 3.5V supply through the inductor 26. Then the switch 28 is opened at the same moment that the switch 30 is closed. Due to the mode of change of current from the switch 28 opening, a large voltage is developed by the inductor 26. This forces the current flowing in the inductor 26 to flow into the capacitor 32 even when it is at a higher Voltage. The voltage drop across the inductor 26 will reduce relatively quickly its current to zero and its energy is transferred to the capacitor 32. As the current reaches zero, the switch 30 is opened allowing the sequence to start again if the capacitor 32 needs more charge. The capacitor 32 is now charged to 8Volts. When the capacitor 32 is at 8 Volts, 1.2 Volts can be achieved by modulating the switch 34 with a mark space ratio of 1.2/8. Then during the data the chunk capacitor 32 will discharge to 1.2V as a worst case. This can then determine the value required for the capacitor 32.

Since there is little to be gained by charging the capacitor 32 through the inductor 26 while discharging it through the inductor 38 since the charging time is in any case much longer that the discharge time. This leads to an alternative arrangement of using a common inductor in place of inductors 26 and 38 and through the use of time multiplexed switches.
The value of capacitor 32 can be calculated from:
Vout is now 1.2V so I=P÷Vout=750 mW÷1.2V=0.625 A
Assuming T=6.6 ms as above, then the voltage drop over the capacitor is Vdrop=8V−1.2V=6.8V
Then, the capacitance of capacitor 32=IT÷Vdrop=(0.625 A×6.6 ms)−6.8V=607 uF
The use of the switch mode power supply can therefore serve to reduce a capacitor from 1.6 mF at 3.5V to 0.6 mFat 8V.

Turning now to FIG. 5, there is illustrated an optical drive system 42 comprising an optical disk 44 rotatably driven by way of a motor 46 and from which data is retrieved, or to which data is recorded, by way of an optical pick-up 48. A decoder and servo controller 50 is provided for delivering control signals to, and receiving signals from, the optical pick-up 48 and also for controlling the motor 46. The decoder and servo controller is likewise arranged by means of line 52 for connection to the host system.

The decoder and servo controller 50 is also arranged to output a control signal 54 delivered to a power supply system 56 which, in accordance with an embodiment of the present invention is arranged to receive input power by input line 58 and to deliver an output power signal 60 for use by the decoder and servo controller 50 in controlling operation of the optical drive system 42.

As will be appreciated, the power supply system 56 is associated with a temporary energy store illustrated in this embodiment by means of a capacitor 62, the charging, and discharging of which, is synchronised and controlled so as to supplement the power requirement of the optical drive system 42 as discussed above.

It will therefore be appreciated that the invention provides for means for deriving a data stream having a bit rate below that required for data recordal/playback and in which the peak power requirement, from for example the onboard power supply is advantageously limited.

1. A method of processing digital data (10), comprising the steps of forming a plurality of discrete bursts of data (12) from the digital data, charging a charge storage device (32) during periods (14) between the discrete bursts of data, and subsequently discharging the charge storage device (32) during the discrete bursts of data (12) so as to provide at least part of the power required during the data bursts (12).

2. A method as claimed in claim 1, wherein a plurality of the discrete bursts (18) form an active period (16) and the data stream is divided into a plurality of active periods (16) separated by idle periods.

3. A method as claimed in claim 2, wherein the charge storage device (32) is charged during the idle period.

4. A method as claimed claim 1, wherein the charge storage device (38) comprises a capacitor.

5. A method as claimed in claim 4, wherein the capacitor forms part of a switch-mode power supply.

6. A method as claimed in claim 4 and including a charging inductor (26) and a discharging inductor (38).

7. A method as claimed in claim 4 and wherein the charging and discharging is achieved by way of a common inductor through the control of appropriate switches to allow for the charging and subsequent discharging.

8. A method as claimed in claim 1, wherein the data processing comprises data recording.

9. A method as claimed in claim 1, wherein the data processing includes data playback.

10. A method as claimed in claim 8 and including the step of processing a digital data stream as part of an optical disk system.

11. A digital data processing device including means for forming a plurality of discrete bursts of data (12) from the digital data, charge storage means (32) arranged to be charged via a power supply for the device, control means arranged to charge the charge storage device (32) during periods (14) between the discrete bursts of data (12), and subsequently to discharge the charge storage device (32) during the discrete bursts (1) of data so as to provide at least part of the power required during the data bursts(12).

12. A device as claimed in claim 11, wherein the means for dividing the digital data stream is arranged so as to provide a plurality of discrete data bursts as an active period, and for dividing the data stream into a plurality of such active periods divided by idle periods.

13. A device as claimed in claim 12, wherein the charge storage device is charged during the idle periods.

14. A device as claimed in claim 11, wherein the charge storage device includes a capacitor (32).

15. A device as claimed in claim 14, wherein the charge storage means forms part of a switch mode power supply arrangement.

16. A device as claimed in claim 15 and including a charging inductor (26) and a discharging inductor (38).

17. A device as claimed in claim 15 and including a common inductor for both charging and discharging and switch means controlled for achieving the required charging and discharging through the common inductor.

18 A device as claimed in claim 11, wherein the device forms part of a digital data recording/playback system.
